(19) United States
(12) Patent Application Publication
(10) Pub. No.: US 2005/0054214 A1
(43) Pub. Date: Mar. 10, 2005

(54) Method for mitigating chemical vapor deposition phosphorus doping oxide surface induced defects

(76) Inventors: Lee Jen Chen, Hsinchu (TW); Kuang-Chao Chen, Hsinchu (TW); Chin-Hsiang Lin, Hsinchu (TW)

Correspondence Address: Stout, Uxa, Buyan & Mullins, LLP, 4 Venture, Suite 300, Irvine, CA, 92618, US

(21) Appl. No.: 10/661,089

(22) Filed: Sep. 10, 2003

(51) Int. Cl. H01L 21/31

(52) U.S. Cl. 438/778

(57) ABSTRACT

A method for mitigating defect formation in a phosphosilicate glass layer of a semiconductor device includes forming an oxide cap upon the phosphosilicate glass layer via a chemical vapor deposition process.

### BACKGROUND OF THE INVENTION

1. Field of the Invention

The present invention relates generally to semiconductor fabrication. The present invention relates more particularly to a method for mitigating phosphorus doping oxide surface induced defects which occur following a chemical vapor deposition (CVD) semiconductor fabrication process.

2. Description of Related Art

Chemical vapor deposition (CVD) systems are well known. Chemical vapor deposition systems are commonly used to form thin films upon the surfaces of substrates during the fabrication of a wide variety of semiconductor devices. For example, chemical vapor deposition systems are used to form dopant, dielectric and passivation layers upon semiconductor wafers during the fabrication of light emitting diodes (LEDs) and integrated circuits (ICs).

During the chemical vapor deposition process, one or more reactant gases are introduced into a reactor chamber. The rate at which reactant gases are introduced into the reactor chamber can be carefully controlled. In this manner, the various layers needed to define the desired device are provided.

It is often desirable to form a phosphosilicate glass (PSG) passivation layer over a substrate, such as a silicon substrate, as well as any intermediate layers formed upon the substrate. The passivation layer protects the underlying layers from damage caused by environmental factors, such as ambient moisture and pollutants contained in the air. The passivation layer also provides some degree of mechanical protection.

However, although the use of such a phosphosilicate glass passivation layer has proven generally useful for its intended purposes, phosphosilicate glass passivation layers possess inherent deficiencies which detract from their overall effectiveness and desirability. For example, after annealing the phosphosilicate glass layer, phosphorus atoms tend to migrate toward the outer or upper surface of the phosphosilicate glass layer. These phosphorus atoms then react with ambient moisture to undesirably affect the formation of defects in the phosphosilicate glass layer. These defects may facilitate the entry of harmful ambient substances into the layers below, thus mitigating the effectiveness of the phosphosilicate glass layer.

As such, although the prior art has recognized, to a limited extent, the problem of forming an adequate and reliable passivation layer upon semiconductor devices during the chemical vapor deposition process, the proposed solutions may not have, to date, been altogether effective in providing a satisfactory remedy. Therefore, it may be desirable to form a passivation layer which is resistant to defect formation due to the effects of ambient moisture upon phosphorus atoms therein, so as to provide a passivation layer having enhanced effectiveness.

### BRIEF SUMMARY OF THE INVENTION

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents.

The present invention specifically addresses and tends to alleviate the above mentioned deficiencies associated with the prior art. More particularly, according to one aspect the present invention comprises a method for mitigating defect formation in a phosphosilicate glass layer, wherein the method comprises forming an oxide cap upon the phosphosilicate glass layer via a chemical vapor deposition process.

According to another aspect, the present invention comprises a method for mitigating defect formation in a passivation layer of a semiconductor device, wherein the method comprises forming a glass layer upon a substrate and forming a cap oxide layer upon the glass layer.

According to another aspect, the present invention comprises a wafer comprising a substrate, a glass passivation layer covering at least a portion of the substrate, and a cap oxide layer formed upon at least a portion of the glass passivation layer.

According to another aspect, the present invention comprises a die comprising a substrate, a glass passivation layer covering at least a portion of the substrate, and a cap oxide layer formed upon at least a portion of the glass passivation layer.

According to another aspect, the present invention comprises a semiconductor device comprising a substrate, a glass passivation layer covering at least a portion of the substrate, and a cap oxide layer formed upon at least a portion of the glass passivation layer.

These, as well as other aspects and advantages of the present invention, will be more apparent from the following description and drawings, wherein like elements are referenced by like numerals. It is understood that changes in the specific structure shown and described may be made within the scope of the claims, without departing from the spirit of the invention.

### BRIEF DESCRIPTION OF THE DRAWINGS

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

FIG. 1 is a fragmentary cross-sectional view of a silicon substrate having a phosphosilicate glass layer formed thereon according to contemporary methodology;

FIG. 2 is a fragmentary cross-sectional view of the silicon substrate and phosphosilicate glass layer of FIG. 1, showing the migration of phosphorus atoms toward the upper surface of the phosphosilicate glass layer;

FIG. 3 is a fragmentary cross-sectional view of the silicon substrate and phosphosilicate glass layer of FIG. 2, showing ambient moisture reacting with the migrated phosphorus atoms to cause defect formation in the phosphosilicate glass layer;

FIG. 4 is a fragmentary cross-sectional view of a silicon substrate having a phosphosilicate glass layer formed thereon and also having a cap oxide layer formed upon the phosphosilicate glass layer according to the present invention;

FIG. 5 is a fragmentary cross-sectional view of the silicon substrate, phosphosilicate glass layer, and cap oxide layer of FIG. 4, showing the migration of phosphorus atoms toward the upper surface of the phosphosilicate glass layer; and

FIG. 6 is a fragmentary cross-sectional view of the silicon substrate, phosphosilicate glass layer, and cap oxide layer of FIG. 5, showing ambient moisture not reacting with the migrated phosphorus atoms because the phosphosilicate glass layer is protected from the ambient moisture by the cap oxide layer.

### DETAILED DESCRIPTION OF THE PREFERRED EMBODIMENTS

Reference will now be made in detail to the presently preferred embodiments of the invention, examples of which are illustrated in the accompanying drawings. Illustrated embodiments described herein are presented by way of example and not by way of limitation, and the process steps and structures described herein do not cover a complete process flow. The present invention may be practiced in conjunction with various integrated circuit fabrication techniques that are conventionally used in the art, and only so much of the commonly practiced process steps are included herein as are necessary to provide an understanding of the present invention.

The present invention provides a method for mitigating defect formations in a phosphosilicate glass layer, wherein the method includes forming an oxide cap upon the phosphosilicate glass layer via a chemical vapor deposition process. In accordance with another aspect, a method for mitigating defect formation in a passivation layer of a semiconductor device comprises forming a glass layer on a substrate and forming a cap oxide layer on the glass layer.

The forming of a glass layer preferably comprises formation of a phosphosilicate glass layer. The substrate preferably comprises a silicon substrate. However, as those skilled in the art will appreciate, various other glass and substrate materials may likewise be suitable.

The substrate preferably has at least one semiconductor layer formed thereon. For example, the substrate may have a plurality of integrated circuits (IC's) or light emitting diodes (LED's) formed thereon. The substrate will typically comprises a wafer which is subsequently cut or diced into a plurality of individual die which are then used to fabricate semiconductor devices.

Forming the glass layer upon the substrate preferably comprises forming the glass layer via a chemical vapor deposition process. However, those skilled in the art will appreciate that various other processes may likewise be suitable.

Similarly, forming the cap oxide layer upon the glass layer preferably comprises forming the cap oxide layer via a chemical vapor deposition process. Again, those skilled in the art will appreciate that various other processes may likewise be suitable.

A chamber of the reactor within which the glass and cap oxide chemical vapor deposition processes are performed is preferably not opened or broken between the glass and cap oxide chemical vapor deposition processes. The ability to form the glass and cap oxide layers upon the substrate without having to break the chamber of the chemical vapor deposition reactor has several substantial advantages. For example, breaking the chamber between process can be an undesirably time consuming and costly process. Moreover, breaking the chamber can afford the potential for contaminating or otherwise damaging the semiconductors being processed therein.

Forming a cap oxide layer upon the glass layer preferably comprises forming an undoped oxide layer upon the glass layer. Forming a glass layer upon a substrate preferably comprises forming a phosphorus doped oxide film upon the substrate.

The glass layer and/or the cap oxide layer is preferably formed by a plasma enhanced chemical vapor deposition process, a sub-atmosphere chemical vapor deposition process, or an atmospheric ambient chemical vapor deposition process. Those skilled in the art will appreciate that various other processes may similarly be suitable for forming the glass layer and/or the cap oxide layer.

The cap oxide layer is preferably formed to have a thickness greater than 300 Angstroms. The phosphorus blocking capability of the cap oxide layer is preferably at least 11% by weight.

The cap oxide layer is preferably formed either via the use of SiH₄ and N₂O reacting gases or via the use of TEOS and O₂ reactant gases. Those skilled in the art will appreciate that various other gases may similarly be used to form the cap oxide layer.

The cap oxide layer process temperature is preferably between approximately 350° C. and approximately 600° C. The glass layer process temperature is preferably between approximately 450° C. and approximately 650° C.

Forming the cap oxide layer optionally comprises forming an inter-layer dielectric, an inter-poly dielectric and/or an inter-metal dielectric layer.

The present invention further provides various structures, such as a wafer including a substrate, a glass passivation layer covering at least a portion of the substrate, and a cap oxide layer formed on at least a portion of the glass passivation layer. In another aspect, a die is provided comprising a substrate, a glass passivation layer covering at least a portion of the substrate, and a cap oxide layer formed upon at least a portion of the glass passivation layer. In accordance with yet another aspect, the present invention provides a semiconductor device having a substrate, a glass passivation layer covering at least a portion of the substrate, and a cap oxide layer formed upon at least a portion of the glass passivation layer.

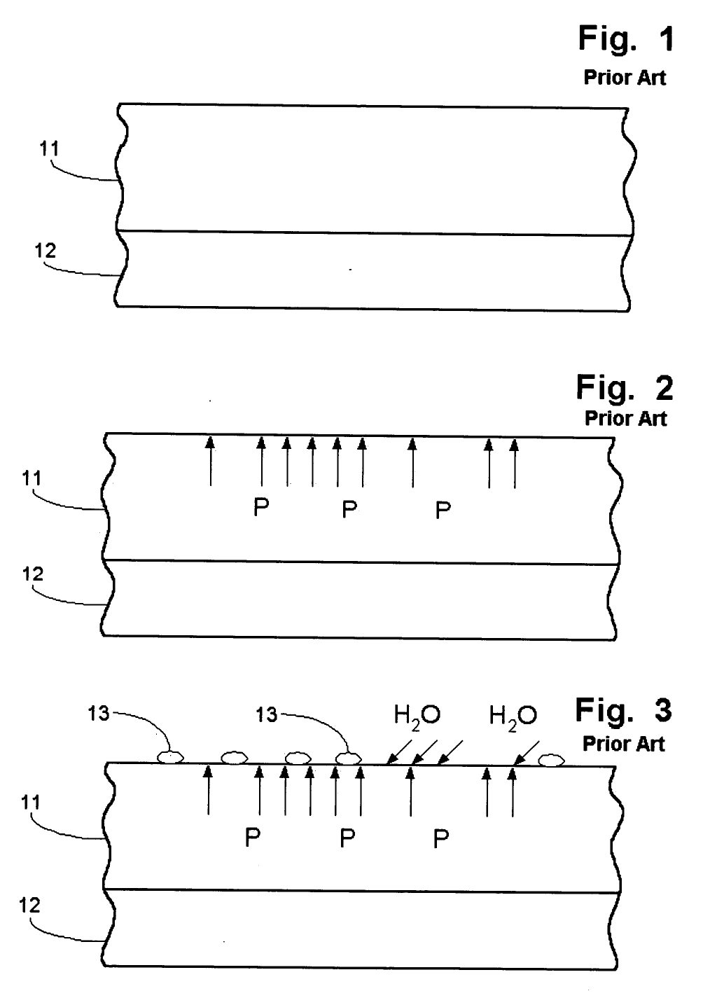

Referring more particularly to the drawings, FIGS. 1-3 depict the process of undesirable defect formation in a phosphosilicate glass passivation layer formed upon a silicon substrate according to contemporary methodology.

With particular reference to FIG. 1, a phosphosilicate glass layer 11 is formed upon a silicon substrate 12, such as via a chemical vapor deposition process. As discussed above, the phosphosilicate glass layer 11 defines a passivation layer which protects the underling semiconductor device(s) formed upon the substrate 12.

The substrate 12 as depicted in FIGS. 1-6 may depict the substrate defined by a wafer, the substrate of a die, or the substrate of a semiconductor device such as an integrated circuit or light emitting diode.

With particular reference to FIG. 2, after the substrate 12 and the glass layer 11 are annealed, phosphorus atoms (designated by P) tend to migrate toward the upper surface of the glass layer 11 (as indicated by the upwardly pointing arrows).

With particular reference to FIG. 3, typically after a period of days ambient moisture (designated by H₂O) reacts (as indicated by the diagonal arrows) with the phosphorus atoms that have migrated to the surface of the glass layer 11. This reaction tends to form undesirable defects in the glass layer 11 which can mitigate the glass layer's utility as a passivation layer and which may lead to failure of the semiconductor device.

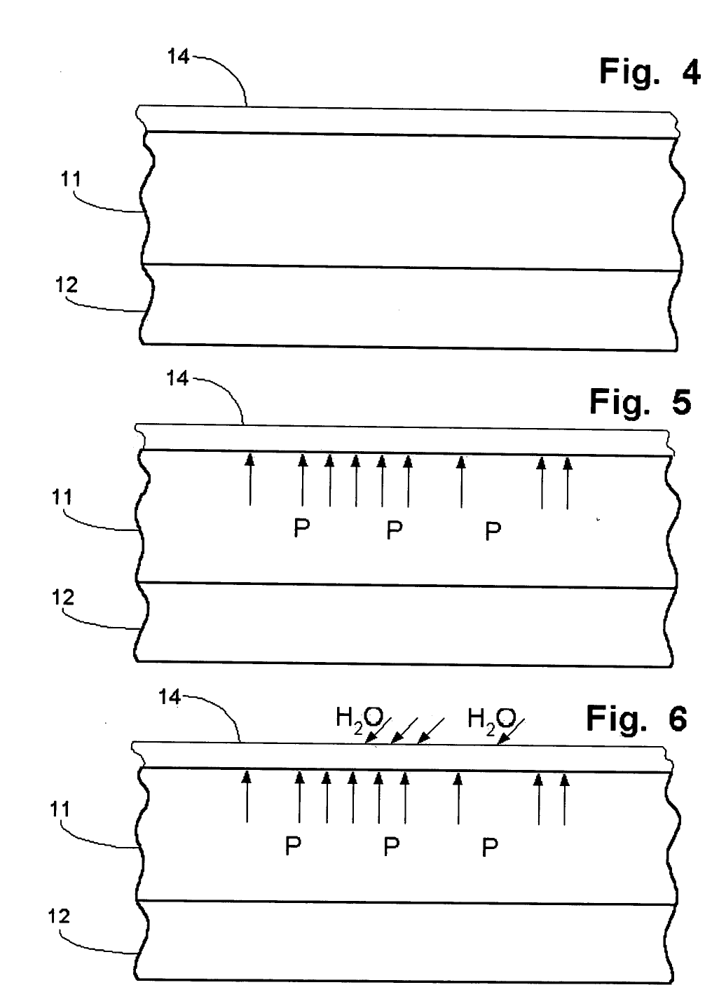

FIGS. 4-6 depict a process of defect mitigation in a phosphosilicate glass passivation layer in accordance with an illustrated embodiment of the present invention, wherein a cap oxide layer is formed upon the phosphosilicate glass passivation layer.

Referring now to FIG. 4, a cap oxide layer 14 is formed upon a phosphosilicate glass layer 11. As mentioned above, this cap oxide layer is preferably formed without opening or breaking the reactor chamber between the process of forming the phosphosilicate glass layer 11 and the process of forming the cap oxide layer 14.

Turning now to FIG. 5, phosphorus atoms still tend to migrate toward the upper surface of the phosphosilicate glass layer 11 after the annealing process. However, such migration is substantially mitigated from continuing into the cap oxide layer 14 as a result of the cap oxide layer.

Referring now to FIG. 6, the cap oxide layer 14 substantially mitigates contact of ambient moisture with the migrated phosphorus atoms. Thus, reactions between such ambient moisture and the phosphorus atoms and the consequent formation of defects in the glass layer 11 are substantially mitigated.

The following table provides experimental data regarding testing of an embodiment of the present invention. Wafer number 1 was a control wafer which did not have a cap oxide layer and which had 15,924 defects one day after rapid thermal annealing. Wafer numbers 2-6 had a cap oxide and layer had between 19 and 62 defects one day after rapid thermal annealing.

| | | | Cap | Defects | Defects | Defects |
|---|---|---|---|---|---|---|
| Wa- | | P % | Oxide | After | After | After RTP + |
| fer | Purpose | Wt. | Depth | Deposit | RTP | 1 Day |
| 1 | Control | 8 | W/0 | 18 | 22 | 15924 |
| 2 | Cap oxide | 5 | 1 KA | 13 | 38 | 44 |
| 3 | effect with P % | 8 | 1 KA | 43 | 52 | 62 |
| 4 | | 11 | 1 KA | 15 | 37 | 41 |
| 5 | Cap oxide | 8 | 300 A | 13 | 15 | 19 |
| 6 | thickness effect | 8 | 500 A | 28 | 42 | 51 |

Wafers 2-4 were formed with different amounts of phosphorus doping (P % Wt.) while maintaining the cap oxide depth (Cap Oxide Depth) constant at 1 kAngstrom. Wafers 5 and 6 had different cap oxide depths while maintaining the amount of phosphorus doping constant at 8% by

Defect scans were performed on the wafer immediately after the chemical vapor deposition process (Defects After Deposit), after rapid thermal annealing (Defects After RTP), and one day after rapid thermal annealing (Defects After RTP+1 Day). The defect count is tabulated in each instance.

It is clear that all five of the cap oxide test wafers had far fewer defects than the control wafer one day after rapid thermal annealing.

The phosphosilicate glass layer, in combination with the cap oxide layer, may be used to achieve planarization of a substrate of an integrated circuit. That is, phosphosilicate glass and cap oxide may be selectively deposited upon the integrated circuit so as to tend to level or fill in low portions thereof. Thus, phosphosilicate glass and cap oxide may be used to form inter-layer dielectrics (ILDs) in accordance with the present invention.

A phosphosilicate glass layer, in combination with the cap oxide layer may find various other applications with respect to the formation of integrated circuits in accordance with the present invention. A phosphosilicate glass and cap oxide composite layer may, for example, be used as an inter-poly dielectric layer or inter-metal dielectric layer, as well as an inter-layer dielectric layer.

It is understood that the exemplary method described herein and shown in the drawings represents only presently preferred embodiments of the invention. Indeed, various modifications and additions may be made to such embodiments without departing from the spirit and scope of the invention. For example, the use of various processes other than chemical vapor deposition are contemplated. Thus, these and other modifications and additions may be obvious to those skilled in the art and may be implemented to adapt the present invention for use in a variety of different applications.

1. A method for mitigating defect formation in a phosphosilicate glass layer, the method comprising forming an oxide cap upon the phosphosilicate glass layer via a chemical vapor deposition process.

2. A method for mitigating defect formation in a passivation layer of a semiconductor device, the method comprising:
forming a glass layer upon a substrate; and
forming a cap oxide layer upon the glass layer.

3. The method as recited in claim 2, wherein forming a glass layer comprises forming a phosphosilicate glass layer.

4. The method as recited in claim 2, wherein the substrate comprises a silicon substrate.

5. The method as recited in claim 2, wherein the substrate has at least one semiconductor layer formed thereon.

6. The method as recited in claim 2, wherein forming the cap oxide layer upon the glass layer comprises forming the cap oxide layer via a chemical vapor deposition process.

7. The method as recited in claim 2, wherein:
forming the glass layer upon the substrate comprises forming the glass layer via a first chemical vapor deposition process;
forming the cap oxide layer upon the glass layer comprises forming the cap oxide layer via a second chemical vapor deposition process; and
wherein a reactor within which the first and second chemical vapor deposition processes are performed is not broken between the first and second chemical vapor deposition processes.

8. The method as recited in claim 2, wherein forming a cap oxide layer upon the glass layer comprises forming an undoped oxide layer upon the glass layer.

9. The method as recited in claim 2, wherein forming a cap oxide layer upon the glass layer comprises forming an undoped oxide layer upon a P doped oxide film.

10. The method as recited in claim 2, wherein at least one of the glass layer and the cap oxide is formed by a process selected from the group consisting of:
a plasma enhanced chemical vapor deposition process;
a sub-atmosphere chemical vapor deposition process; and
an atmospheric ambient chemical vapor deposition process.

11. The method as recited in claim 2, wherein the cap oxide layer is formed to have a thickness greater than 300 Angstroms.

12. The method as recited in claim 2, wherein a phosphorus blocking capability of the cap oxide layer is at least 11% by weight.

13. The method as recited in claim 2, wherein the cap oxide layer is formed by SiH₄ and N₂O reacting gases.

14. The method as recited in claim 2, wherein the cap oxide layer is formed by TEOS and O₂ reacting gases.

15. The method as recited in claim 2, wherein the cap oxide layer process temperature is between approximately 350° C. and approximately 600° C.

16. The method as recited in claim 2, wherein the glass layer process temperature is between approximately 450° C. and approximately 650° C.

17. The method as recited in claim 2, wherein forming the cap oxide layer comprises forming at least one of inter-layer dielectric, inter-poly dielectric and inter-metal dielectric layers.

18. A semiconductor device comprising:
a substrate;
a glass passivation layer covering at least a portion of the substrate; and
a cap oxide layer formed upon at least a portion of the glass passivation layer.

19. The semiconductor device as recited in claim 19, wherein the substrate comprises silicon.

20. The semiconductor device as recited in claim 19, further comprising at least one semiconductor layer formed upon the substrate.

21. The semiconductor device as recited in claim 19, wherein the glass comprises phosphosilicate glass.

22. The semiconductor device as recited in claim 19, wherein the cap oxide layer is formed to have a thickness greater than approximately 300 A.

23. The semiconductor device as recited in claim 19, wherein a phosphorus blocking capability of the cap oxide layer is at least 11% by weight.

24. The semiconductor device as recited in claim 19, wherein forming the cap oxide layer comprises forming at least one of inter-layer dielectric, inter-poly dielectric and inter-metal dielectric layers.
